(19) United States
(12) Patent Application Publication
(10) Pub. No.: US 2004/0243872 A1
(43) Pub. Date: Dec. 2, 2004

(54) METHOD FOR USING SERIAL FLASH MEMORY AS PROGRAM STORAGE MEDIA FOR MICROPROCESSOR

(76) Inventors: Li-Chun Tu, Taipei City (TW); Hung-Cheng Kuo, Hsin-Chu City (TW); Ping-Sheng Chen, Chia-Yi Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/709,765

(22) Filed: May 27, 2004

(30) Foreign Application Priority Data
May 29, 2003 (TW) 092114631
Aug. 27, 2003 (TW) 092123664

(51) Int. Cl. G11C 5/00; G06F 12/00

(52) U.S. Cl. 713/401; 711/103; 711/167

(57) ABSTRACT

A method for dynamically adjusting an operating speed of a microprocessor for the microprocessor to access at least a serial flash memory(together with a random access memory). The method includes reducing an executing speed of the microprocessor if the required data in the serial flash memory (or the random access memory) is not well prepared and executing the microprocessor at a normal speed if the required data in the serial flash memory(or the random access memory) is well prepared.

### BACKGROUND OF INVENTION

1. Field of the Invention

The invention relates to a method for using a serial flash memory as the program storage media for a microprocessor, and more particularly, to apply only a serial flash or a serial flash together with a random access memory as the program storage media for a microprocessor.

2. Description of the Prior Art

For microprocessor execution, it is necessary to provide instant programming code access. So that the data transmission speed between the microprocessor and the code storage memories is important. In the prior-art technique, we use parallel flash for code storage. When a microprocessor asks a program memory to provide data (programming codes), an access location and other control signals corresponding to the desired programming code should be emitted from the microprocessor. Afterwards, the program memory, such as a read-only memory (ROM) or a flash memory, has to send the desired programming code(s) to the microprocessor within a certain period of time after the program memory receives the access location and the control signals from the microprocessor. Please refer to FIG. 1, which is a schematic diagram showing how a microprocessor 10 accesses a program memory 12 according to the prior art. The microprocessor 10 emits an access address and a control signal towards the program memory 12, and the program memory 12 returns corresponding digital data (programming codes) back to the microprocessor 10 after receiving the access address and the control signals.

Regarding the evaluation of the performance of a memory, the most important part is the concern of access time and access speed. All of the processes, including the microprocessor emitting the access address and related control signals, the memory acquiring the access address data, the memory returning the corresponding digital data to the microprocessor, and the microprocessor actually receiving the desired digital data and finishing the data analyses, take an access cycle of the memory; that is, if the access cycle of the memory is set as 60 ns, the whole desired time for executing the whole processes is 60 ns. Please continue to refer to the prior-art embodiment shown in FIG. 1. A complete access operation between the microprocessor 10 and the program memory 12 usually includes four following operating steps: (a) emitting the access address by the microprocessor 10, (b) waiting for the programming codes returned from the program memory 12, (c) analyzing the programming codes, and (d) emitting a new access address by the microprocessor 10. If the program memory 12 cannot finish the above-mentioned four operating steps within one access cycle, data loss, data clog, and inaccuracy of execution of the programming codes may occur.

The speed of the program memory 12 has to satisfy a certain requirement so that the microprocessor 10 can smoothly access and execute the programming codes in the program memory 12. Therefore, some memories, such as the serial flash memory, occupying less system sources and saving pin counts for the system at the expense of the access speed can not be applied in the prior-art structure installed with the microprocessor. Moreover, if we use a dynamic random access memory (DRAM) as the storage media of program memory, we must make sure the required instructions can feed back from the dynamic random access memory in certain microprocessor cycles (usually a memory access cycle), so that we may need very high speed DRAM for satisfying the requirement all the ti me.

In addition, a typical simulation process has to reflect the practical operational conditions of the original system. According to the simulation results, some possible errors may be rectified in advance. In general, an in-circuit emulator (ICE) duplicates and imitates the behavior of a chip and the in-circuit emulator emulates by using programming techniques and special machine features to permit executing codes written for the chip that it imitates. In brief, the in-circuit emulator is a hardware component used for emulating behaviors of the microprocessor circuit and externally connected to the original microprocessor system as an expansion of the original microprocessor system. With the in-circuit emulator, designers can perform debug-simulating operations for the microprocessor system. Please refer to FIG. 2, which is a schematic diagram showing an in-circuit emulator 24 emulating a microprocessor system 20 according to the prior art. As shown in FIG. 2, a chip 20 (the microprocessor system), an in-circuit emulator 24, a program memory 22, and an external clock generator 26 are included. Please refer to both FIG. 1 and FIG. 2. The in-circuit emulator 24 replaces the chip 20 (the microprocessor) to emulate actual operations of the chip 20, which includes the microprocessor 10 shown in FIG. 1. In the prior-art embodiment, an operating clock of the in-circuit emulator 24 is provided from the external clock generator 26 having no relation with the emulated chip 20 (the microprocessor system 20). The program memory 22 can be used to provide instructions for operating the in-circuit emulator 24, and the in-circuit emulator 24 can be used to provide the access address and related control signals toward the emulated chip. Afterwards, the chip returns the corresponding digital data to the in-circuit emulator 24 according to the access address and the related control signals. The in-circuit emulator duplicates and imitates the behavior of a chip according to the above-mentioned description.

However, by either utilizing the in-circuit emulator or executing some present simulation software, actual operating conditions of the microprocessor system 20 with a serial flash memory are still hard to imitate. Because when a cost-effective, simple, and slow serial flash memory, is integrated with a high-speed microprocessor, such as the high-speed microprocessor system 20 shown in FIG. 2, the fluctuation of the clock, interruption, and suspension of operation should be taken into consideration of design. According to the prior art, on the premise that it is almost impossible to use a (external) clock generator 26 to imitate those dynamic operations, it is needless to consider the possibility of the integration between the low-speed memory and the high-speed microprocessor system.

### SUMMARY OF INVENTION

It is therefore a primary objective of the claimed invention to provide a method for using a serial flash memory or a serial flash memory together with a random access memory as program memory to provide the instructions of a microprocessor. We can dynamically adjusting the operating speed of the microprocessor to access the serial flash memory (together with the random access memory) and to solve the above-mentioned problems.

In the embodiments according to the present invention, operating (executing) speed of a microprocessor is arranged by adjusting an operating clock. We set a buffering/controlling device in the microprocessor system for outputting the operating clock to the microprocessor and for consecutively accessing a predetermined number of data (programming codes) from a serial flash memory (together with a random access memory). When the microprocessor requires data, it will first check whether the buffering/controlling device stores the desired data (programming codes) of the microprocessor. If the buffering/controlling device stores the desired data, the microprocessor accesses the desired data directly from the buffering/controlling device; on the other hand, the buffering/controlling device will slow down or temporarily stop the operating clock, so that the microprocessor will suspend and retain the current conditions due to the disappearance of the operating clock. After the serial flash memory (together with the random access memory) searches and returns the desired programming codes of the microprocessor, the buffering/controlling device will recover the operating clock. Therefore, the operating clock can be dynamically controlled, and using the serial flash memory (together with the random access memory) as program memory is possible.

In the present invention, we further disclose a technique for dynamically adjusting an operating clock of a microprocessor emulator. The microprocessor emulator is electrically connected to a buffering/controlling device, and the buffering/controlling device outputs the operating clock to the microprocessor emulator for operating the microprocessor emulator. Therefore, the buffering/controlling device can dynamically adjust the operating clock according to whether the access address emitted from the microprocessor emulator is located in the buffering/controlling device. The mechanism of the present invention can emulate the behavior of a microprocessor to access a low-speed serial flash memory by utilizing the buffering/controlling device.

According to the claimed invention, we disclosure a method for dynamically adjusting an operating speed of a microprocessor for the microprocessor to access at least a serial flash memory (together with a random access memory) including reducing an executing speed of the microprocessor if data in the serial flash memory (together with the random access memory) is not well prepared and executing the microprocessor at a normal speed if data in the serial flash memory (together with the random access memory) is well prepared.

According to the claimed invention, we disclosure a method for dynamically adjusting an operating speed of a microprocessor emulator, the emulator can emulate the behavior of microprocessor system with a serial flash memory (together with a random access memory).

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a schematic diagram showing how a microprocessor accesses a program memory according to the prior art.

FIG. 2 is a schematic diagram showing an in-circuit emulator emulating a microprocessor system according to the prior art.

FIG. 3 is a functional block diagram of an embodiment according to the present invention.

FIG. 4 is a schematic diagram of a detailed embodiment shown in FIG. 3.

FIG. 5 is a timing chart including a covering mask signal, the operating clock, the access address, and the programming codes.

FIG. 6 is a flowchart of an embodiment according to the present invention.

FIG. 7 is a functional block diagram of another embodiment according to the present invention.

FIG. 8 is a schematic diagram of a detailed embodiment according to the present invention.

FIG. 9 is a block diagram of a processing system according to another embodiment of the present invention.

FIG. 10 is a block diagram of a processing system according to another embodiment of the present invention.

### DETAILED DESCRIPTION

Several preferred embodiments according to the present invention are introduced as follows. The method includes reducing an executing speed of the microprocessor if data in the serial flash memory (together with the dynamic random access memory) is not well prepared and executing the microprocessor at a normal speed if data in the serial flash memory (together with the dynamic random access memory) is well prepared. The buffering/controlling device can be replaced by a microprocessor-operating-speed control device. The following embodiments utilizing the buffering/controlling device are only examples according to the present invention.

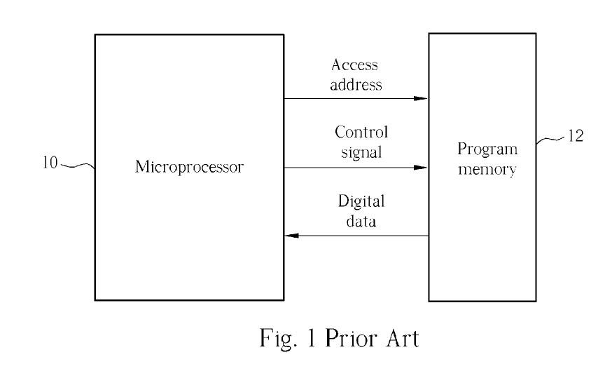

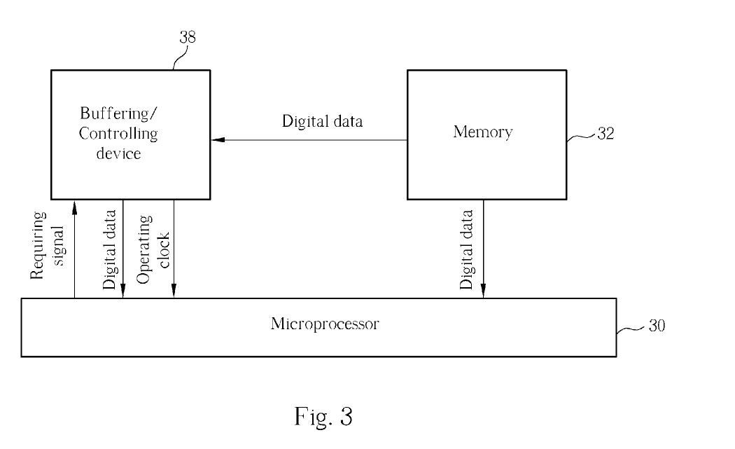

Please refer to FIG. 3, which is a functional block diagram of an embodiment according to the present invention. The structure shown in FIG. 3 includes a buffering/controlling device 38, a microprocessor 30, and a serial flash memory 32. The serial flash memory 32 stores a plurality of digital instructions. In contrast with the prior-art embodiment shown in FIG. 1, during the access process, the serial flash memory 32 in the present embodiment may not support enough bit rate (programming codes access rate) that microprocessor 30 needed. When the microprocessor 30 operates at a high speed, we can use the present invention to help the microprocessor 30 access the (low-speed)serial flash memory 32 via the buffering/controlling device 38 for avoiding data loss or data clog.

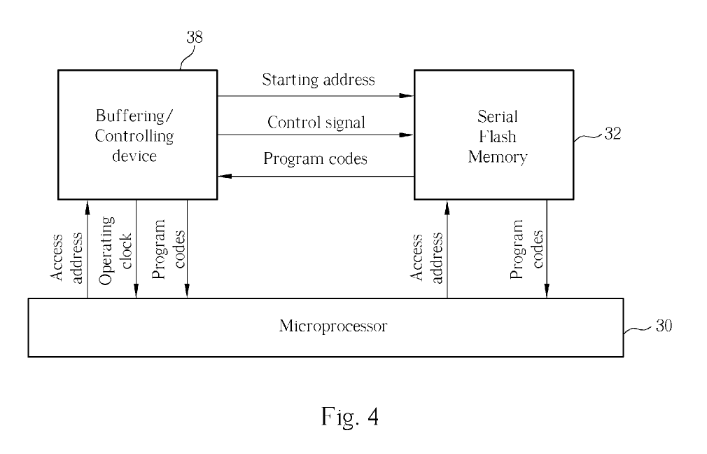

Please continue to refer to FIG. 4. In the present embodiment, the microprocessor 30 does not directly acquire the desired digital data from the serial flash memory 32 but utilizes the buffering/controlling device 38 beforehand to consecutively access a plurality of digital data in the serial flash memory 32 instead. The buffering/controlling device 38 outputs an operating clock to the microprocessor 30 so as to slow down/stop microprocessor 30; that is, when the operating clock disappears, the operations of the microprocessor 30 will suspend, when the operating clock slow down, the operations of the microprocessor 30 will also slow down. The buffering/controlling device 38 can consecutively access a predetermined number of programming codes in the serial flash memory 32. When the microprocessor 30 requires the programming codes and accesses the buffering/controlling device 38, the microprocessor 30 emits an access address corresponding to the programming codes to the buffering/controlling device 38 so that the buffering/controlling device 38 can judge whether the access address emitted from the microprocessor 30 is located in the buffering/controlling device 38. If the buffering/controlling device 38 stores the programming codes required by the microprocessor 30, the microprocessor 30 directly receives the desired programming codes from the buffering/controlling device 38. On the other hand, if the buffering/controlling device 38 does not store the programming codes required by the microprocessor 30 (for instance, the microprocessor 30 is in jump condition), the buffering/controlling device 38 will stop the outputting of the operating clock so that the microprocessor 30 will suspend and retain the current conditions due to the disappearance of the operating clock. In the meantime, the buffering/controlling device 38 transmits the access address corresponding to the programming codes to the serial flash memory 32. After receiving the access address, the serial flash memory 32 will search and return the searched programming codes to the buffering/controlling device 38 and the microprocessor 30(for fasten the whole access process). The buffering/controlling device 38 then recovers the operating clock for the microprocessor 30 so that the microprocessor 30 can access the programming codes. With the structure and method according to the present embodiment, the microprocessor 30 can execute the codes when accessing the low-speed serial flash memory 32.

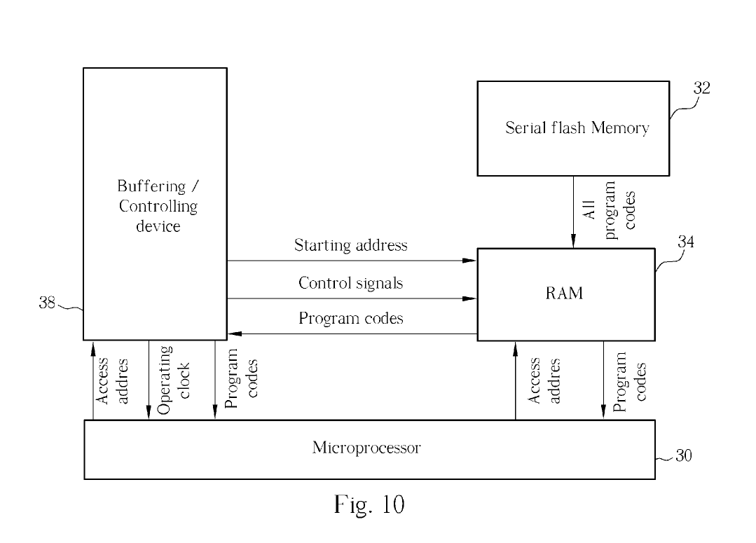

Please refer to FIG. 10. In the present embodiment, the program is stored in the random access memory 34(it's usually a dynamic random access memory). We first load the instructions from the serial flash memory 32 to the random access memory 34,then the microprocessor 30 will execute the program via the random access memory 34. The microprocessor 30 does not directly acquire the desired digital data from the random access memory 34 but utilizes the buffering/controlling device 38 beforehand to consecutively access a plurality of digital data in the random access memory 34 instead. The buffering/controlling device 38 outputs an operating clock to the microprocessor 30 so as to slow down/stop microprocessor 30; that is, when the operating clock disappears, the operations of the microprocessor 30 will suspend, when the operating clock slow down, the operations of the microprocessor 30 will also slow down. The buffering/controlling device 38 can consecutively access a predetermined number of programming codes in the random access memory 34. When the microprocessor 30 requires the programming codes and accesses the buffering/controlling device 38, the microprocessor 30 emits an access address corresponding to the programming codes to the buffering/controlling device 38 so that the buffering/controlling device 38 can judge whether the access address emitted from the microprocessor 30 is located in the buffering/controlling device 38. If the buffering/controlling device 38 stores the programming codes required by the microprocessor 30, the microprocessor 30 directly receives the desired programming codes from the buffering/controlling device 38. On the other hand, if the buffering/controlling device 38 does not store the programming codes required by the microprocessor 30 (for instance, the microprocessor 30 is in jump condition), the buffering/controlling device 38 will stop the outputting of the operating clock so that the microprocessor 30 will suspend and retain the current conditions due to the disappearance of the operating clock. In the meantime, the buffering/controlling device 38 transmits the access address corresponding to the programming codes to the random access memory 34. After receiving the access address, the random access memory 34 will search and return the searched programming codes to the buffering/controlling device 38 and the microprocessor 30(for fasten the whole access process). The buffering/controlling device 38 then recovers the operating clock for the microprocessor 30 so that the microprocessor 30 can access the programming codes. With the structure and method according to the present embodiment, the microprocessor 30 can execute the codes when accessing the low-speed random access memory 34.

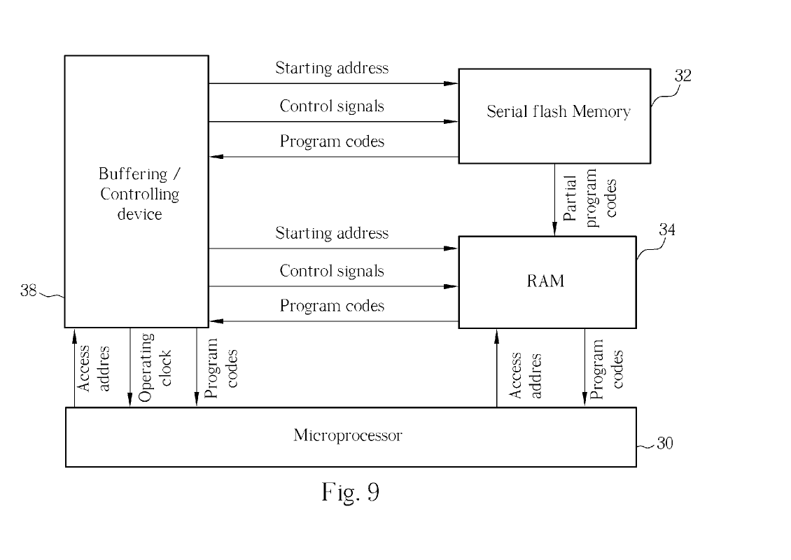

Please continue to refer to FIG. 9. In the present embodiment, the program is partially stored in the random access memory 34(it's usually a dynamic random access memory) and partially stored in the serial flash memory 32. We first load partial of the instructions from the serial flash memory 32 to the random access memory 34, then the microprocessor 30 will execute the program via the random access memory 34 or the serial flash memory 32. Usually, for faster response speed, we will put frequently used codes into random access memory 34, and if the required instructions are available in the random access memory 34, the buffering/controlling device 38 will fetch the codes from the random access memory 34, else the buffering/controlling device 38 fetch the codes from the serial flash memory 32. In fact, the microprocessor 30 does not directly acquire the desired digital data from the random access memory 34 or the serial flash memory 32 but utilizes the buffering/controlling device 38 beforehand to consecutively access a plurality of digital data in the random access memory 34 or the serial flash memory 32 instead. The buffering/controlling device 38 outputs an operating clock to the microprocessor 30 so as to slow down/stop microprocessor 30; that is, when the operating clock disappears, the operations of the microprocessor 30 will suspend, when the operating clock slow down, the operations of the microprocessor 30 will also slow down. The buffering/controlling device 38 can consecutively access a predetermined number of programming codes in the random access memory 34 or the serial flash memory 32. When the microprocessor 30 requires the programming codes and accesses the buffering/controlling device 38, the microprocessor 30 emits an access address corresponding to the programming codes to the buffering/controlling device 38 so that the buffering/controlling device 38 can judge whether the access address emitted from the microprocessor 30 is located in the buffering/controlling device 38. If the buffering/controlling device 38 stores the programming codes required by the microprocessor 30, the microprocessor 30 directly receives the desired programming codes from the buffering/controlling device 38. On the other hand, if the buffering/controlling device 38 does not store the programming codes required by the microprocessor 30 (for instance, the microprocessor 30 is in jump condition), the buffering/controlling device 38 will stop the outputting of the operating clock so that the microprocessor 30 will suspend and retain the current conditions due to the disappearance of the operating clock. In the meantime, the buffering/controlling device 38 transmits the access address corresponding to the programming codes to the random access memory 34 or the serial flash memory 32. After receiving the access address, the random access memory 34 or the serial flash memory 32 will search and return the searched programming codes to the buffering/controlling device 38 and the microprocessor 30(for fasten the whole access process). The buffering/controlling device 38 then recovers the operating clock for the microprocessor 30 so that the microprocessor 30 can access the programming codes. With the structure and method according to the present embodiment, the microprocessor 30 can execute the codes when accessing the low-speed random access memory 34 or the serial flash memory 32.

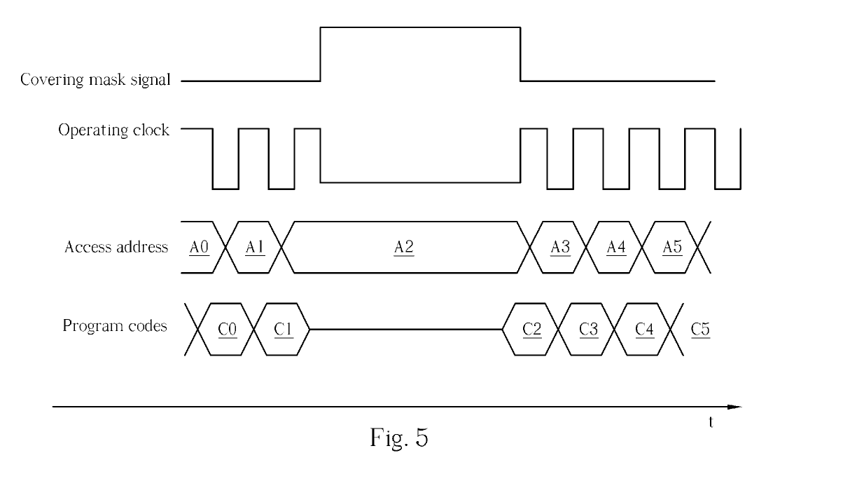

In the embodiments of the present invention, the buffering/controlling device 38 can stop outputting the operating clock by marking the operating clock. The mechanism can be achieved by setting a covering mask signal in the buffering/controlling device 38. Please refer to FIG. 5, which is a timing chart showing a covering mask signal, the operating clock, the access address, and the programming codes. Please refer to FIG. 5. When the access address A2 (corresponding to the programming code C2) required by the microprocessor 30 is not located in the buffering/controlling device 38, the covering mask signal will be raised to a predetermined voltage level to stop the operating clock. In the meanwhile, the microprocessor 30 retains its current condition (sending the access address A2) because missing of operating clock. When the desired programming code C2 of the microprocessor 30 returns from the serial flash memory 32 or the random access memory 34 to the buffering/controlling device 38 and the microprocessor 30, the covering mask signal will be restored to another predetermined voltage level to release the operating clock and to continue the operations of the microprocessor 30. A front (rising) edge of the covering mask signal represents that the access address (and the corresponding programming codes) of the microprocessor 30 is not located in the buffering/controlling device 38, while the rear (falling) edge of the covering mask signal represents the required programming codes of the microprocessor 30 is found in the serial flash memory 32 or the random access memory 34 and already captured by the buffering/controlling device 38 (and the microprocessor 30). Therefore, by utilizing the buffering/controlling device 38 combined with dynamically adjustable operating clock according to the present invention, the high-speed microprocessor 30 can smoothly access the low-speed serial flash memory 32 or the random access memory 34.

In summary, the present invention utilizes a buffering/controlling device and a covering mask signal to dynamically adjust the operating clock of a microprocessor, so that the microprocessor can smoothly access a memory.

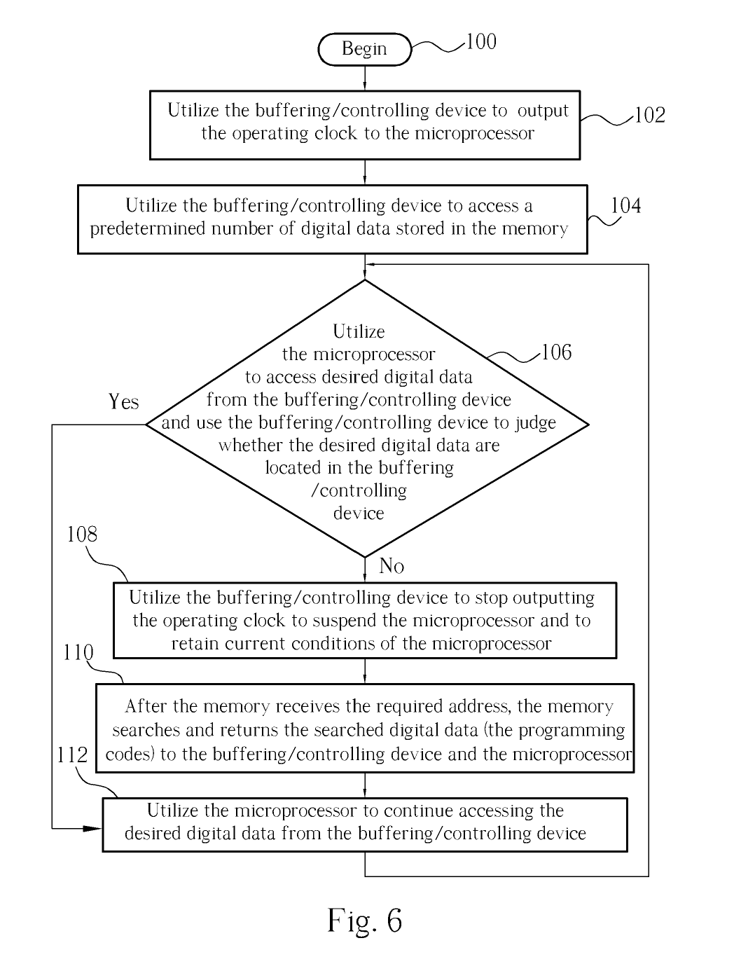

Please refer to FIG. 6, which is a flowchart of an embodiment according to the present invention.

Step 100: Begin;

Step 102: Utilize the buffering/controlling device to output the operating clock to the microprocessor so as to control the microprocessor;

Step 104: Utilize the buffering/controlling device to access a predetermined number of digital data stored in the serial flash memory or the random access memory. In the embodiment shown in FIG. 3, FIG. 4, FIG. 9 and FIG. 10, the buffering/controlling device can consecutively access the predetermined number of programming codes at a starting address in the serial flash memory or the random access memory;

Step 106: Utilize the microprocessor to access desired digital data from the buffering/controlling device and utilize the buffering/controlling device to judge whether the desired digital data (corresponding to the access address) of the microprocessor are located in the buffering/controlling device. If the desired digital data are located in the buffering/controlling device, proceed with Step 112; If the microprocessor desired digital data are not located in the buffering/controlling device, proceed with Step 108.

Step 108: Utilize the buffering/controlling device to stop outputting the operating clock to suspend the microprocessor and to retain current conditions of the microprocessor. For instance, a covering mask signal will be raised to a predetermined voltage level to stop the operating clock. In the meantime, the buffering/controlling device transmits the access address and the control signals to the serial flash memory or the random access memory;

Step 110: After the serial flash memory or the random access memory receives related control signals and the access address corresponding to the required codes, the serial flash memory or the random access memory searches and returns the searched digital data (the programming codes) to the buffering/controlling device and the microprocessor. The buffering/controlling device release the operating clock for the microprocessor (lowering the covering mask signal to a predetermined voltage level), so that the microprocessor can continue to operate;

Step 112: Continue to proceed with normal data access operations; that is, utilize the microprocessor to continue accessing the desired digital data (the programming codes) from the buffering/controlling device. Go back to Step 106 to process additional data.

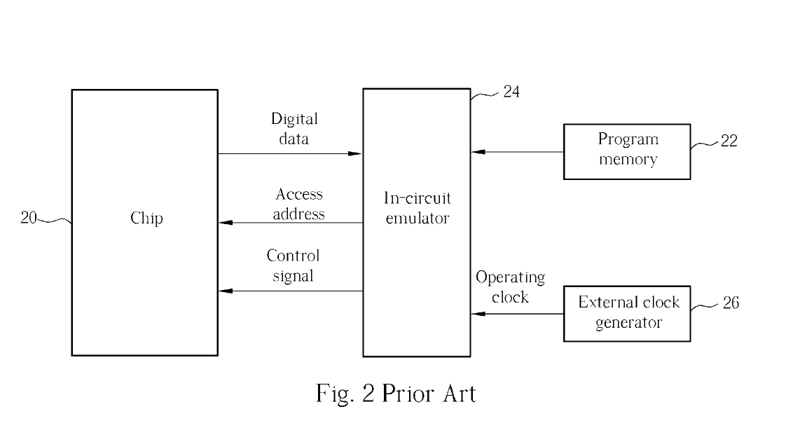

Regarding the emulation of the microprocessor according to the present invention, the above-mentioned characteristics of method and structure are still suitable. Please refer to FIG. 2 (the prior-art embodiment), FIG. 3, and FIG. 4. In order to access a low-speed serial flash memory in the structure of the present invention, an additional buffering/controlling device 38 is installed between the microprocessor 30 and the serial flash memory 32. When the programming code required by the microprocessor 30 is not located in the buffering/controlling device 38, the operating clock will be stopped and the microprocessor 30 will retain its current condition. When the desired programming code of the microprocessor 30 returns from the serial flash memory 32 to the buffering/controlling device 38 and the microprocessor 30, the operating clock will be released and the microprocessor 30 will continue to operate. Since in real circumstances the operating clock of the microprocessor 30 does not regularly appear, the emulator according to the prior art shown in FIG. 2 can imitate neither the dynamic situation nor the mechanism that the buffering/controlling device.

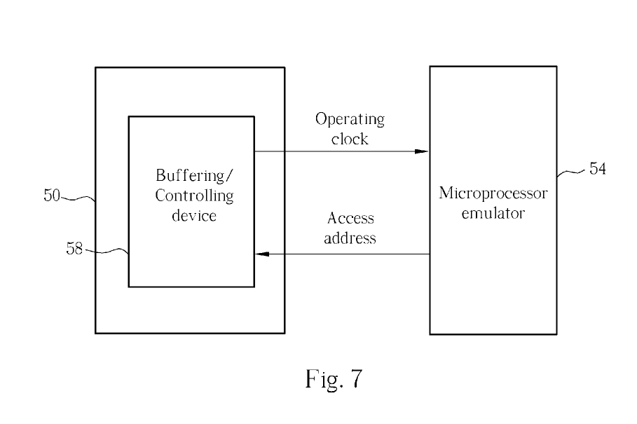

Please refer to FIG. 7, which is a functional block diagram of another embodiment according to the present invention. The present embodiment includes a buffering/controlling device 58 and a microprocessor emulator 54. The buffering/controlling device 58 is installed in a microprocessor system 50, and the buffering/controlling device 58 and the microprocessor emulator 54 are mutually connected. Concerning the previous embodiments shown in FIG. 3 and FIG. 4, the microprocessor emulator 54 corresponds to the microprocessor 30. In order to make the microprocessor emulator 54 authentically emulate the operation of the microprocessor system 50 of the present invention, the buffering/controlling device 58 provides an operating clock to the microprocessor emulator 54 so as to control the microprocessor emulator 54. Whether the buffering/controlling device 58 originally stores a predetermined number of address data, the microprocessor emulator 54 emits an access address to the buffering/controlling device 58 when starting to perform emulating operation. When the access address is located in the buffering/controlling device 58, the buffering/controlling device 58 continues to output the operating clock to the microprocessor emulator 54 to maintain operations of the microprocessor emulator 54. When the access address is not located in the buffering/controlling device 58, the buffering/controlling device 58 will stop outputting the operating clock to the microprocessor emulator 54 so as to suspend the microprocessor emulator 54. Therefore, utilizing the buffering/controlling device 58 to provide with the dynamically adjustable operating clock for the microprocessor emulator 54 directs an effective way to dynamically control the microprocessor emulator 54 and to accurately emulate the microprocessor system 50 with characteristics of the present invention.

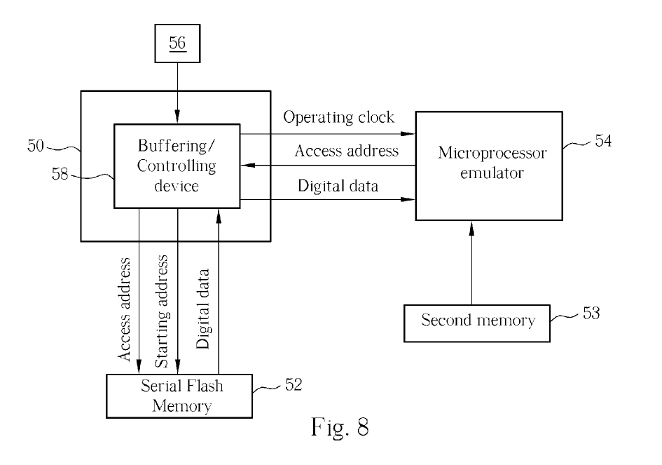

Another approach for emulation of the present embodiment is that the buffering/controlling device 58 automatically recovers to output the operating clock to the microprocessor emulator 54 in order to recover the operations of the microprocessor emulator 54 after a predetermined number of the operating clock cycles pass (the operating clock starts to operate after the buffering/controlling device 58 stops to output the operating clock to suspend the microprocessor emulator 54). Since the emulation process is still different from the actual operation, the connection between a memory and the buffering/controlling device 58 does not matter. If the buffering/controlling device 58 is electrically connected to a low-speed serial flash memory stored with a plurality of digital data, the whole structure (including the buffering/controlling device 58 and the low-speed memory) is almost equal to the embodiment of the present invention shown in FIG. 3 and FIG. 4. Please refer to FIG. 8, which is a schematic diagram of a detailed embodiment according to the present invention. The buffering/controlling device 58 is implemented with a FIFO storage structure and electrically connected to a low-speed serial flash memory 52. The microprocessor emulator 54 is an in-circuit emulator 24. The buffering/controlling device 58 will consecutively access a predetermined number of digital data and corresponding access addresses at a starting address of the serial flash memory 52; that is, those digital data and corresponding access addresses are stored beforehand to the buffering/controlling device 58. When the access address emitted from the microprocessor emulator 54 is located in the buffering/controlling device 58, the buffering/controlling device 58 will deliver the digital data corresponding to the access address to the microprocessor emulator 54. When the access address is not located in the buffering/controlling device 58 (for example, the jump condition executed by the microprocessor 30), the serial flash memory 52 will search and return digital data corresponding to the access address back to the buffering/controlling device 58 and the buffering/controlling device 58 then delivers the searched digital data to the microprocessor emulator 54. In the meantime, the operating clock recovers. Certainly, if the microprocessor emulator 54 is electrically connected to the serial flash memory 52, serial flash memory 52 can directly return the digital data to the microprocessor emulator 54 without any intermediary device such as the buffering/controlling device 58 immediately after the serial flash memory 52 searches the desired digital data corresponding to the access address.

Please notice that, in the present embodiment, the buffering/controlling device 58 can stop outputting the operating clock by covering/marking the operating clock. Therefore, a covering mask signal should be included in the buffering/controlling device 58. When the desired access address of the microprocessor emulator is not located in the buffering/controlling device 58, the buffering/controlling device 58 will raise the value of the covering mask signal to a predetermined voltage level so as to cover the operating clock. After a predetermined number of clock cycles (or after the digital data begin to be returned from the serial flash memory 52 to the buffering/controlling device 58 and the microprocessor emulator 54), the covering mask signal will be recovered to an initial predetermined low voltage level so as to recover the operating clock and to operate the microprocessor emulator 54.

Please continue to refer to FIG. 8. The microprocessor emulator 54 is electrically connected to a second memory 53, which can be a program memory such as a static random access memory (SRAM) or a ROM. A plurality of instructions, which are required for operations of the microprocessor emulator 54, are stored in the second memory 53. When the buffering/controlling device 58 outputs the operating clock to the microprocessor emulator 54, the second memory 53 will deliver related instructions to the microprocessor emulator 54. When the buffering/controlling device 58 suspends to output the operating clock to the microprocessor emulator 54, the microprocessor emulator 54 suspends and is unable to receive any instruction from the second memory 53. In addition, the frequency of the operating clock provided by the buffering/controlling device 58 can be adjusted according to the real situations. The frequency of the operating clock can also be adjusted by being electrically connected to an external clock generator 56. In summary, the microprocessor emulator 54 of the present invention can accurately emulate the performances of the microprocessor system 50 combined with the low-speed serial flash memory 52 and a dynamically adjustable operating clock.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for dynamically adjusting an operating speed of a microprocessor for the microprocessor to access at least a serial flash memory, wherein the serial flash memory is a program memory, and the digital data stored in the serial flash memory is programming data, the method comprising:
(a) reducing an executing speed of the microprocessor if the data that microprocessor required from the serial flash memory is not well prepared; and
(b) executing the microprocessor at a normal speed if the data that microprocessor required from the serial flash memory is well prepared.

2. The method of claim 1, wherein in step (a), reducing the executing speed of the microprocessor makes the executing speed of the microprocessor lower than the normal speed or totally suspends the microprocessor.

3. The method of claim 1, wherein step (a) is capable of being achieved by adjusting an operating clock with an external circuit or with a circuit installed in the microprocessor, by inserting an NOP (No Operation) command among commands, or by keeping a program counter unchanged.

4. The method of claim 1 involved with a buffering/controlling device, the method further comprising:
(c) utilizing the buffering/controlling device to access a predetermined number of digital data stored in the serial flash memory;
(d) utilizing the microprocessor to access desired digital data from the buffering/controlling device;
(e) in step (b), utilizing the microprocessor to access the digital data located in the buffering/controlling device and continuing to operate the microprocessor at the normal speed when the desired digital data of the microprocessor are in the buffering/controlling device;
(f) in step (a), reducing the operating speed of the microprocessor when the desired digital data of the microprocessor are not in the buffering/controlling device; and
(g) after proceeding with step (f), transmitting the desired digital data of the microprocessor from the serial flash memory to the buffering/controlling device and to the microprocessor and recovering the operating speed of the microprocessor so that the microprocessor is capable of accessing the digital data.

5. The method of claim 4 further comprising:
(h) in step (c), utilizing the buffering/controlling device to consecutively access the predetermined number of digital data at a starting address of the serial flash memory; and
(i) in step (d), (e), and (f), utilizing the microprocessor to emit an access address corresponding to the digital data to the buffering/controlling device, so that the buffering/controlling device is capable of judging whether the desired digital data of the microprocessor are located in the buffering/controlling device.

6. The method of claim 4, wherein a first data access rate is set between the buffering/controlling device and the microprocessor, and a second data access rate is set between the memory and the buffering/controlling device, wherein the first data access rate is higher than or equal to the second data access rate.

7. The method of claim 4, wherein the buffering/controlling device is a FIFO storage structure, a dynamic random access memory (DRAM), or a static random access memory (SRAM).

8. A method for dynamically adjusting an operating speed of a microprocessor for the microprocessor to access at least a serial flash memory and a random access memory (RAM), wherein the serial flash memory and the random access memory are program memories, and the digital data stored in the serial flash memory or the random access memory is programming data, the method comprising:
(a) loading partial of the program codes from the serial flash memory to the random access memory before the microprocessor's requiring data; and
(b) reducing an executing speed of the microprocessor if the data that microprocessor required from the serial flash memory or the random access memory is not well prepared; and
(c) executing the microprocessor at a normal speed if the data that microprocessor required from the serial flash memory or the random access memory is well prepared.

9. The method of claim 8, wherein in step (b), reducing the executing speed of the microprocessor makes the executing speed of the microprocessor lower than the normal speed or totally suspends the microprocessor.

10. The method of claim 8, wherein step (b) is capable of being achieved by adjusting an operating clock with an external circuit or with a circuit installed in the microprocessor, by inserting an NOP (No Operation) command among commands, or by keeping a program counter unchanged.

11. The method of claim 8 involved with a buffering/controlling device, the method further comprising:
(d) utilizing the buffering/controlling device to access a predetermined number of digital data stored in the serial flash memory or the random access memory;
(e) utilizing the microprocessor to access desired digital data from the buffering/controlling device;
(f) in step (c), utilizing the microprocessor to access the digital data located in the buffering/controlling device and continuing to operate the microprocessor at the normal speed when the desired digital data of the microprocessor are in the buffering/controlling device;
(g) in step (b), reducing the operating speed of the microprocessor when the desired digital data of the microprocessor are not in the buffering/controlling device; and
(h) after proceeding with step (g), transmitting the desired digital data of the microprocessor from the serial flash memory or the random access memory to the buffering/controlling device and to the microprocessor and recovering the operating speed of the microprocessor so that the microprocessor is capable of accessing the digital data.

12. The method of claim 11 further comprising:
(i) in step (d), utilizing the buffering/controlling device to consecutively access the predetermined number of digital data at a starting address of the serial flash memory or the random access memory; and
(j) in step (e), (f), and (g), utilizing the microprocessor to emit an access address corresponding to the digital data to the buffering/controlling device, so that the buffering/controlling device is capable of judging whether the desired digital data of the microprocessor are located in the buffering/controlling device.

13. The method of claim 11, wherein a first data access rate is set between the buffering/controlling device and the microprocessor, and a second data access rate is set between the serial flash memory and the buffering/controlling device, and a third data access rate is set between the random access memory and the buffering/controlling device, wherein the first data access rate is higher than or equal to the second data access rate, and the first data access rate is higher than or equal to the third data access rate.

14. The method of claim 11, wherein the buffering/controlling device is a FIFO storage structure, a dynamic random access memory (DRAM), or a static random access memory (SRAM).

15. The method of claim 8, wherein the random access memory is a dynamic random access memory (DRAM).

16. A method for dynamically adjusting an operating speed of a microprocessor for the microprocessor to access at least a random access memory (RAM), wherein the random access memory are a program memory, and the digital data stored in the random access memory is programming data, the method comprising:
(a) loading the digital data from a serial flash memory to the random access memory before the microprocessor's requiring data; and
(b) reducing an executing speed of the microprocessor if the data that microprocessor required from the random access memory is not well prepared; and
(c) executing the microprocessor at a normal speed if the data that microprocessor required from the random access memory is well prepared.

17. The method of claim 16, wherein in step (b), reducing the executing speed of the microprocessor makes the executing speed of the microprocessor lower than the normal speed or totally suspends the microprocessor.

18. The method of claim 16, wherein step (b) is capable of being achieved by adjusting an operating clock with an external circuit or with a circuit installed in the microprocessor, by inserting an NOP (No Operation) command among commands, or by keeping a program counter unchanged.

19. The method of claim 16, involved with a buffering/controlling device, the method further comprising:
(d) utilizing the buffering/controlling device to access a predetermined number of digital data stored in the random access memory;
(e) utilizing the microprocessor to access desired digital data from the buffering/controlling device;
(f) in step (c), utilizing the microprocessor to access the digital data located in the buffering/controlling device and continuing to operate the microprocessor at the normal speed when the desired digital data of the microprocessor are in the buffering/controlling device;
(g) in step (b), reducing the operating speed of the microprocessor when the desired digital data of the microprocessor are not in the buffering/controlling device; and
(h) after proceeding with step (g), transmitting the desired digital data of the microprocessor from the random access memory to the buffering/controlling device and to the microprocessor and recovering the operating speed of the microprocessor so that the microprocessor is capable of accessing the digital data.

20. The method of claim 19 further comprising:
(i) in step (d), utilizing the buffering/controlling device to consecutively access the predetermined number of digital data at a starting address of the random access memory; and
(j) in step (e), (f), and (g), utilizing the microprocessor to emit an access address corresponding to the digital data to the buffering/controlling device, so that the buffering/controlling device is capable of judging whether the desired digital data of the microprocessor are located in the buffering/controlling device.

21. The method of claim 19, wherein a first data access rate is set between the buffering/controlling device and the microprocessor, and a second data access rate is set between the random access memory and the buffering/controlling device, wherein the first data access rate is higher than or equal to the second data access rate.

22. The method of claim 19, wherein the buffering/controlling device is a FIFO storage structure, a dynamic random access memory (DRAM), or a static random access memory (SRAM).

23. The method of claim 16, wherein the random access memory is a dynamic random access memory (DRAM).

24. A method for dynamically adjusting an operating speed of a microprocessor emulator for the microprocessor emulator to emulate the operation with a serial flash memory, the method comprising:
(a) reducing an executing speed of the microprocessor emulator for a certain period; and
(b) executing the microprocessor emulator at a normal speed after the certain period.

25 The method of claim 24, wherein in step (a) and (b), the certain period depends on the serial flash access time.

26. The method of claim 24, wherein in step (a), reducing the executing speed of the microprocessor emulator makes the executing speed of the microprocessor emulator lower than the normal speed or totally suspends the microprocessor emulator.

27. The method of claim 24, wherein step (a) is capable of being achieved by adjusting an operating clock with an external circuit or with a circuit installed in the microprocessor emulator, by inserting an NOP (No Operation) command among commands, or by keeping a program counter unchanged.

28. The method of claim 24, wherein the microprocessor emulator is electrically connected to a microprocessor system that further comprises a buffering/controlling device, the method comprising:
(c) utilizing the microprocessor emulator to emit an access address to the buffering/controlling device;
(d) in step (b), operating the microprocessor emulator at the normal speed when the access address is in the buffering/controlling device; and
(e) in step (a), reducing the operating speed of the microprocessor emulator when the access address is not in the buffering/controlling device.

29. The method of claim 28 further comprising:
(f) after proceeding with step (e), recovering the operating speed of the microprocessor emulator after a predetermined number of clock cycles.

30. The method of claim 24, wherein the microprocessor emulator is electrically connected to a second memory, and the second memory is capable of being used to transmit at least an instruction to the microprocessor emulator.

31. The method of claim 30, wherein the second memory is a static random access memory (SRAM), a flash memory, or a dynamic random access memory (DRAM).

32. The method of claim 28, wherein the buffering/controlling device is electrically connected to the serial flash memory, and the serial flash memory stores a plurality of digital data, the method further comprising:
(g) utilizing the buffering/controlling device to access a predetermined number of digital data stored in the serial flash memory;
(h) in step (d), utilizing the buffering/controlling device to transmit the digital data corresponding to the access address to the microprocessor emulator when the access address is in the buffering/controlling device; and
(i) after proceeding with step (e), transmitting the digital data corresponding to the access address from the serial flash memory to the buffering/controlling device and to the microprocessor emulator and recovering the executing speed of the microprocessor emulator.

33. The method of claim 32, wherein in step (g), the buffering/controlling device consecutively accesses the predetermined number of digital data at a starting address of the serial flash memory.

34. The method of claim 32, wherein the serial flash memory is a program memory, and the digital data stored in the serial flash memory are programming codes.

35. The method of claim 32, wherein a first data access rate is set between the buffering/controlling device and the microprocessor emulator, and a second data access rate is set between the serial flash memory and the buffering/controlling device, wherein the first data access rate is higher than or equal to the second data access rate.

36. The method of claim 24, wherein the operating clock's frequency of the microprocessor emulator is capable of being adjusted by an external clock device.

37. The method of claim 28, wherein the buffering/controlling device is a FIFO storage structure, a dynamic random access memory (DRAM), or a static random access memory (SRAM).

38. The method of claim 24, wherein the microprocessor emulator is an in-circuit emulator.
